(19) United States
(12) Patent Application Publication
(10) Pub. No.: US 2005/0136681 A1
(43) Pub. Date: Jun. 23, 2005

(54) Method and apparatus for removing photoresist from a substrate

(75) Inventors: Vaidyanathan Balasubramaniam, Richardson, TX (US); Koichiro Inazawa, Peabody, MA (US)

Correspondence Address: PILLSBURY WINTHROP SHAW PITTMAN, LLP, P.O. BOX 10500, MCLEAN, VA, 22102, US

(73) Assignee: Tokyo Electron Limited, Tokyo (JP)

(21) Appl. No.: 10/743,275

(22) Filed: Dec. 23, 2003

(51) Int. Cl. C23F 1/00; B44C 1/22; C03C 15/00; C03C 25/68; H01L 21/302

(52) U.S. Cl. 438/710; 438/725; 216/67; 156/345.35

(57) ABSTRACT

A method and system for removing photoresist from a substrate in a plasma processing system comprising: introducing a process gas comprising NₓO_{y}, wherein x, y represent integers greater than or equal to unity. Additionally, the process chemistry can further comprise the addition of an inert gas, such as a Noble gas (i.e., He, Ne, Ar, Kr, Xe, Rn). The present invention further presents a method for forming a feature in a thin film on a substrate, wherein the method comprises: forming a dielectric layer on a substrate; forming a photoresist pattern on the dielectric layer; transferring the photoresist pattern to the dielectric layer by etching; and removing the photoresist from the dielectric layer using a process gas comprising NₓO_{y}, wherein x and y are integers greater than or equal to unity.

### FIELD OF THE INVENTION

The present invention relates to a method and apparatus for removing photoresist from a substrate.

### BACKGROUND OF THE INVENTION

During semiconductor processing, a (dry) plasma etch process can be utilized to remove or etch material along fine lines or within vias or contacts patterned on a silicon substrate. The plasma etch process generally involves positioning a semiconductor substrate with an overlying patterned, protective layer, for example a photoresist layer, in a processing chamber. Once the substrate is positioned within the chamber, an ionizable, dissociative gas mixture is introduced within the chamber at a pre-specified flow rate, while a vacuum pump is throttled to achieve an ambient process pressure. Thereafter, a plasma is formed when a fraction of the gas species present are ionized by electrons heated via the transfer of radio frequency (RF) power either inductively or capacitively, or microwave power using, for example, electron cyclotron resonance (ECR). Moreover, the heated electrons serve to dissociate some species of the ambient gas species and create reactant specie(s) suitable for the exposed surface etch chemistry. Once the plasma is formed, selected surfaces of the substrate are etched by the plasma. The process is adjusted to achieve appropriate conditions, including an appropriate concentration of desirable reactant and ion populations to etch various features (e.g., trenches, vias, contacts, etc.) in the selected regions of the substrate. Such substrate materials where etching is required include silicon dioxide (SiO₂), low dielectric constant (i.e., low-k) dielectric materials, poly-silicon, and silicon nitride. Once the pattern is transferred from the patterned photoresist layer to the underlying dielectric layer, using, for example, dry plasma etching, the remaining layer of photoresist, and post-etch residues, are removed via an ashing (or stripping) process. For instance, in conventional ashing processes, the substrate having the remaining photoresist layer is exposed to an oxygen plasma formed from the introduction of diatomic oxygen (O₂) and ionization/dissociation thereof.

### SUMMARY OF THE INVENTION

In one aspect of the invention, a method for removing photoresist from a substrate comprises: disposing the substrate in a plasma processing system, the substrate having a dielectric layer formed thereon with photoresist overlying the dielectric layer, wherein the photoresist provides a mask for etching a feature into the dielectric layer; introducing a process gas comprising NₓO_{y}, wherein x and y are integers greater than or equal to unity; forming a plasma from the process gas in the plasma processing system; and removing the photoresist from the substrate with said plasma.

In another aspect of the invention, a method of forming a feature in a dielectric layer on a substrate is described comprising: forming the dielectric layer on the substrate; forming a photoresist pattern on the dielectric layer; transferring the photoresist pattern to the dielectric layer by etching; and removing the photoresist from the dielectric layer using a plasma formed with a process gas comprising NₓO_{y}, wherein x and y are integers greater than or equal to unity.

In another aspect of the invention, a plasma processing system for removing photoresist from a substrate is described comprising: a plasma processing chamber for facilitating the formation of a plasma from a process gas; and a controller coupled to the plasma processing chamber and configured to execute a process recipe utilizing the process gas to form a plasma to remove the photoresist from the substrate, wherein the process gas comprises NₓO_{y}, and x and y are integers greater than or equal to unity.

### BRIEF DESCRIPTION OF THE DRAWINGS

In the accompanying drawings:

FIGS. 1A, 1B, and 1C show another schematic representation of a typical procedure for pattern etching a thin film;

FIG. 2 shows a simplified schematic diagram of a plasma processing system according to an embodiment of the present invention;

FIG. 3 shows a schematic diagram of a plasma processing system according to another embodiment of the present invention;

FIG. 4 shows a schematic diagram of a plasma processing system according to another embodiment of the present invention;

FIG. 5 shows a schematic diagram of a plasma processing system according to another embodiment of the present invention;

FIG. 6 shows a schematic diagram of a plasma processing system according to another embodiment of the present invention;

FIG. 7 presents a method of etching an anti-reflective coating (ARC) layer on a substrate in a plasma processing system according to an embodiment of the present invention; and

FIG. 8 presents a method of forming a bilayer mask for etching a thin film on a substrate according to another embodiment of the present invention.

### DETAILED DESCRIPTION OF SEVERAL EMBODIMENTS

In material processing methodologies, pattern etching comprises the application of a thin layer of light-sensitive material, such as photoresist, to an upper surface of a substrate, that is subsequently patterned in order to provide a mask for transferring this pattern to the underlying thin film during etching. The patterning of the light-sensitive material generally involves exposure by a radiation source through a reticle (and associated optics) of the light-sensitive material using, for example, a micro-lithography system, followed by the removal of the irradiated regions of the light-sensitive material (as in the case of positive photoresist), or non-irradiated regions (as in the case of negative resist) using a developing solvent.

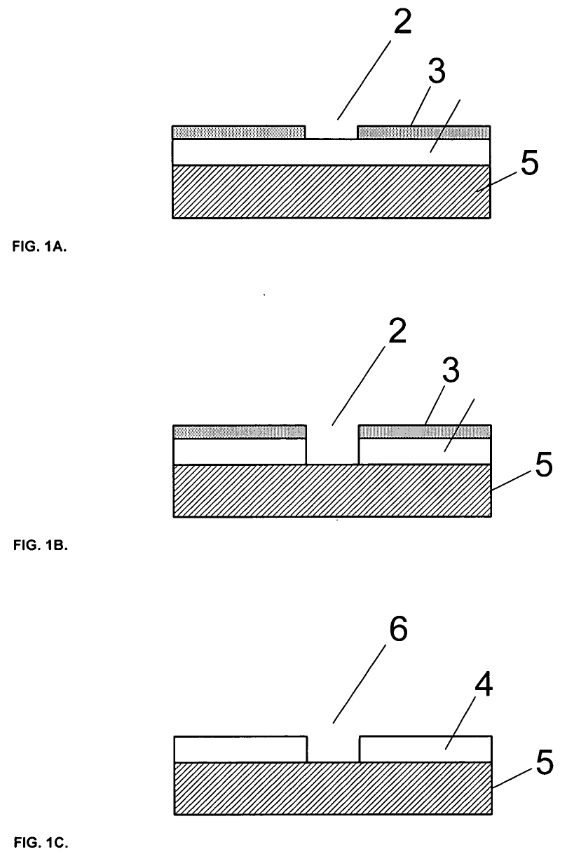

For example, as shown in FIGS. 1A through 1C, a mask comprising light-sensitive layer 3 with pattern 2 (such as patterned photoresist) can be utilized for transferring feature patterns into a thin film 4 on a substrate 5. The pattern 2 is transferred to the thin film 4 using, for instance, dry plasma etching, in order to form feature 6, and upon completion of etching, the mask 3 is removed.

In one embodiment, a process gas comprising a NₓO_{y} is utilized for removing mask 3, wherein x, y represent integers greater than or equal to unity. The process gas comprising NₓO_{y} can include at least one of NO, NO₂, and N₂O. Alternately, the process gas can further comprise an inert gas, such as a Noble gas (i.e., He, Ne, Ar, Kr, Xe, Rn).

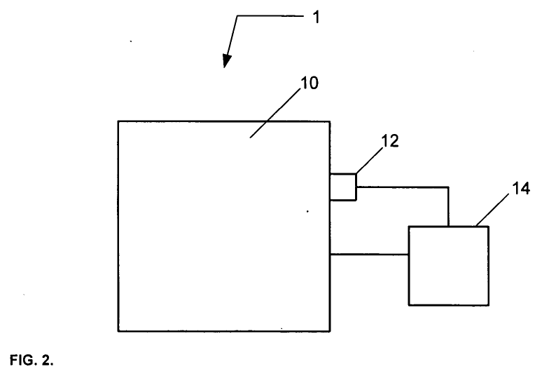

According to one embodiment, a plasma processing system 1 is depicted in FIG. 2 comprising a plasma processing chamber 10, a diagnostic system 12 coupled to the plasma processing chamber 10, and a controller 14 coupled to the diagnostic system 12 and the plasma processing chamber 10. The controller 14 is configured to execute a process recipe comprising at least one of the above-identified chemistries (i.e. NₓO_{y}, etc.) to remove photoresist from a substrate. Additionally, controller 14 is configured to receive at least one endpoint signal from the diagnostic system 12 and to post-process the at least one endpoint signal in order to accurately determine an endpoint for the process. In the illustrated embodiment, plasma processing system 1, depicted in FIG. 2, utilizes a plasma for material processing. Plasma processing system 1 can comprise an etch chamber, and ash chamber, or combination thereof.

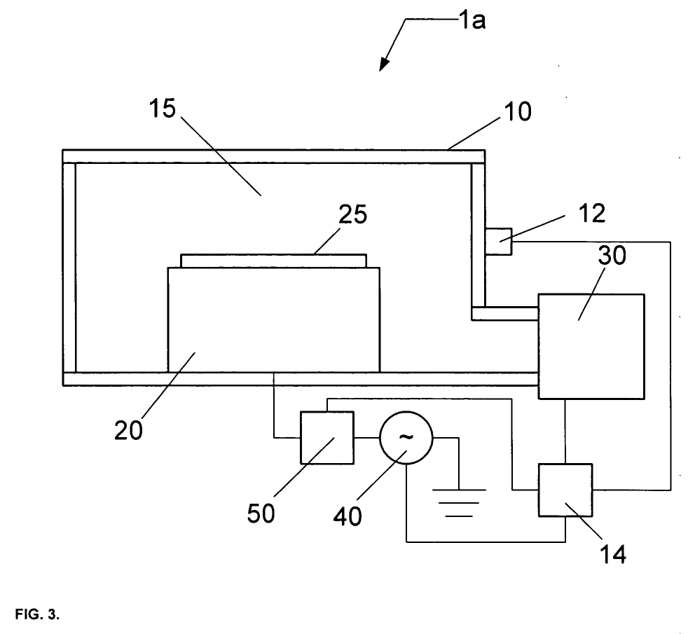

According to the embodiment depicted in FIG. 3, plasma processing system 1a can comprise plasma processing chamber 10, substrate holder 20, upon which a substrate 25 to be processed is affixed, and vacuum pumping system 30. Substrate 25 can be a semiconductor substrate, a wafer or a liquid crystal display. Plasma processing chamber 10 can be configured to facilitate the generation of plasma in processing region 15 adjacent a surface of substrate 25. An ionizable gas or mixture of gases is introduced via a gas injection system (not shown) and the process pressure is adjusted. For example, a control mechanism (not shown) can be used to throttle the vacuum pumping system 30. Plasma can be utilized to create materials specific to a pre-determined materials process, and/or to aid the removal of material from the exposed surfaces of substrate 25. The plasma processing system 1a can be configured to process substrates of any desired size, such as 200 mm substrates, 300 mm substrates, or larger.

Substrate 25 can be affixed to the substrate holder 20 via an electrostatic clamping system. Furthermore, substrate holder 20 can further include a cooling system including a re-circulating coolant flow that receives heat from substrate holder 20 and transfers heat to a heat exchanger system (not shown), or when heating, transfers heat from the heat exchanger system. Moreover, gas can be delivered to the back-side of substrate 25 via a backside gas system to improve the gas-gap thermal conductance between substrate 25 and substrate holder 20. Such a system can be utilized when temperature control of the substrate is required at elevated or reduced temperatures. For example, the backside gas system can comprise a two-zone gas distribution system, wherein the helium gas gap pressure can be independently varied between the center and the edge of substrate 25. In other embodiments, heating/cooling elements, such as resistive heating elements, or thermoelectric heaters/coolers can be included in the substrate holder 20, as well as the chamber wall of the plasma processing chamber 10 and any other component within the plasma processing system 1a.

In the embodiment shown in FIG. 3, substrate holder 20 can comprise an electrode through which RF power is coupled to the processing plasma in process space 15. For example, substrate holder 20 can be electrically biased at a RF voltage via the transmission of RF power from a RF generator 40 through an impedance match network 50 to substrate holder 20. The RF bias can serve to heat electrons to form and maintain plasma. In this configuration, the system can operate as a reactive ion etch (RIE) reactor, wherein the chamber and an upper gas injection electrode serve as ground surfaces. A typical frequency for the RF bias can range from about 0.1 MHz to about 100 MHz. RF systems for plasma processing are well known to those skilled in the art.

Alternately, RF power is applied to the substrate holder electrode at multiple frequencies. Furthermore, impedance match network 50 serves to improve the transfer of RF power to plasma in plasma processing chamber 10 by reducing the reflected power. Match network topologies (e.g. L-type, π-type, T-type, etc.) and automatic control methods are well known to those skilled in the art.

Vacuum pump system 30 can include a turbo-molecular vacuum pump (TMP) capable of a pumping speed up to about 5000 liters per second (and greater) and a gate valve for throttling the chamber pressure. In conventional plasma processing devices utilized for dry plasma etch, a 1000 to 3000 liter per second TMP is generally employed. TMPs are useful for low pressure processing, typically less than about 50 mTorr. For high pressure processing (i.e., greater than about 100 mTorr), a mechanical booster pump and dry roughing pump can be used. Furthermore, a device for monitoring chamber pressure (not shown) can be coupled to the plasma processing chamber 10. The pressure measuring device can be, for example, a Type 628B Baratron absolute capacitance manometer commercially available from MKS Instruments, Inc. (Andover, Mass.).

Controller 14 comprises a microprocessor, memory, and a digital I/O port capable of generating control voltages sufficient to communicate and activate inputs to plasma processing system 1a as well as monitor outputs from plasma processing system 1a. Moreover, controller 14 can be coupled to and can exchange information with RF generator 40, impedance match network 50, the gas injection system (not shown), vacuum pump system 30, as well as the backside gas delivery system (not shown), the substrate/substrate holder temperature measurement system (not shown), and/or the electrostatic clamping system (not shown). For example, a program stored in the memory can be utilized to activate the inputs to the aforementioned components of plasma processing system 1a according to a process recipe in order to perform the method of removing photoresist from a substrate. One example of controller 14 is a DELL PRECISION WORKSTATION610™, available from Dell Corporation, Austin, Tex.

Controller 14 can be locally located relative to the plasma processing system 1a, or it can be remotely located relative to the plasma processing system 1a. For example, controller 14 can exchange data with plasma processing system 1a using at least one of a direct connection, an intranet, and the internet. Controller 14 can be coupled to an intranet at, for example, a customer site (i.e., a device maker, etc.), or it can be coupled to an intranet at, for example, a vendor site (i.e., an equipment manufacturer). Additionally, for example, controller 14 can be coupled to the internet. Furthermore, another computer (i.e., controller, server, etc.) can, for example, access controller 14 to exchange data via at least one of a direct connection, an intranet, and the internet.

The diagnostic system 12 can include an optical diagnostic subsystem (not shown). The optical diagnostic subsystem can comprise a detector such as a (silicon) photodiode or a photomultiplier tube (PMT) for measuring the light intensity emitted from the plasma. The diagnostic system 12 can further include an optical filter such as a narrow-band interference filter. In an alternate embodiment, the diagnostic system 12 can include at least one of a line CCD (charge coupled device), a CID (charge injection device) array, and a light dispersing device such as a grating or a prism. Additionally, diagnostic system 12 can include a monochromator (e.g., grating/detector system) for measuring light at a given wavelength, or a spectrometer (e.g., with a rotating grating) for measuring the light spectrum such as, for example, the device described in U.S. Pat. No. 5,888,337.

The diagnostic system 12 can include a high resolution Optical Emission Spectroscopy (OES) sensor such as from Peak Sensor Systems, or Verity Instruments, Inc. Such an OES sensor has a broad spectrum that spans the ultraviolet (UV), visible (VIS), and near infrared (NIR) light spectrums. The resolution is approximately 1.4 Angstroms, that is, the sensor is capable of collecting 5550 wavelengths from 240 to 1000 nm. The OES sensor can be equipped with high sensitivity miniature fiber optic UV-VIS-NIR spectrometers which are, in turn, integrated with 2048 pixel linear CCD arrays.

The spectrometers receive light transmitted through single or bundled optical fibers, where the light output from the optical fibers is dispersed across the line CCD array using a fixed grating. Similar to the configuration described above, light emitting through an optical vacuum window is focused onto the input end of the optical fibers via a convex spherical lens. Three spectrometers, each specifically tuned for a given spectral range (UV, VIS and NIR), can form a sensor for a process chamber. Each spectrometer can include an independent A/D converter. And lastly, depending upon the sensor utilization, a full emission spectrum can be recorded every 0.1 to 1.0 seconds.

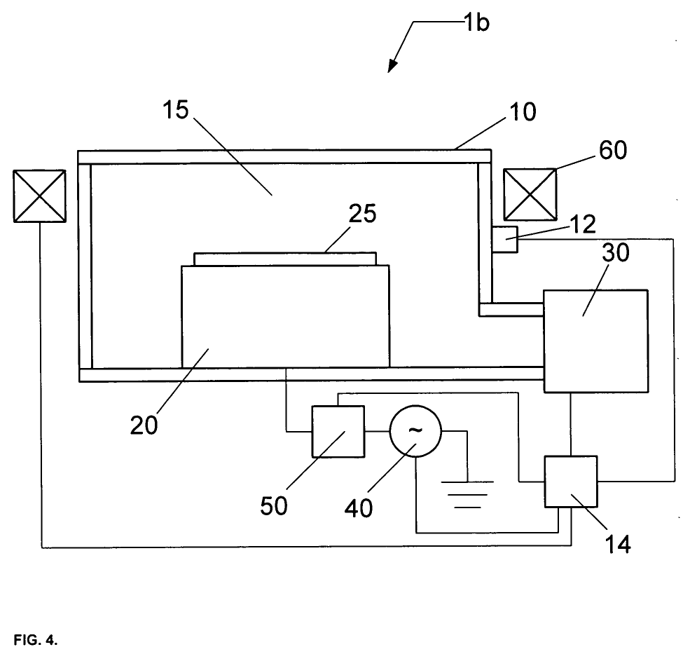

In the embodiment shown in FIG. 4, the plasma processing system 1b can be similar to the embodiment of FIG. 2 or 3 and further comprise either a stationary, or mechanically or electrically rotating magnetic field system 60, in order to potentially increase plasma density and/or improve plasma processing uniformity, in addition to those components described with reference to FIG. 2 and FIG. 3. Moreover, controller 14 can be coupled to magnetic field system 60 in order to regulate the speed of rotation and field strength. The design and implementation of a rotating magnetic field is well known to those skilled in the art.

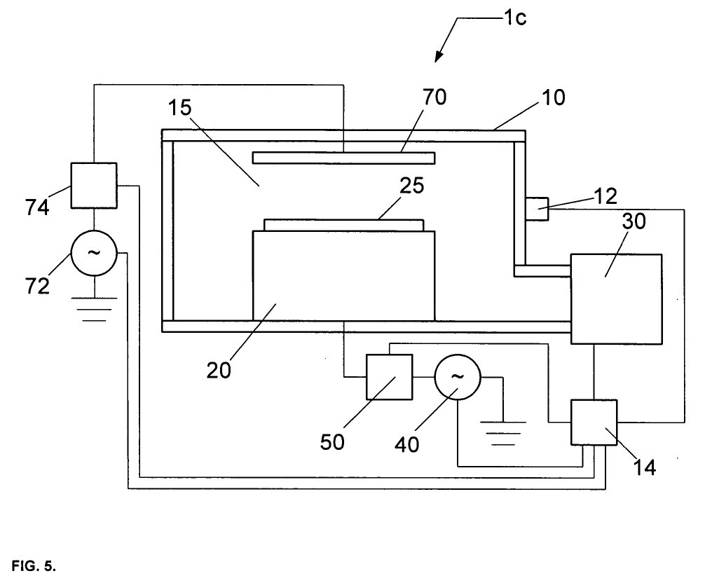

In the embodiment shown in FIG. 5, the plasma processing system 1c can be similar to the embodiment of FIG. 2 or FIG. 3, and can further comprise an upper electrode 70 to which RF power can be coupled from RF generator 72 through impedance match network 74. A frequency for the application of RF power to the upper electrode can range from about 0.1 MHz to about 200 MHz. Additionally, a frequency for the application of power to the lower electrode can range from about 0.1 MHz to about 100 MHz. Moreover, controller 14 is coupled to RF generator 72 and impedance match network 74 in order to control the application of RF power to upper electrode 70. The design and implementation of an upper electrode is well known to those skilled in the art.

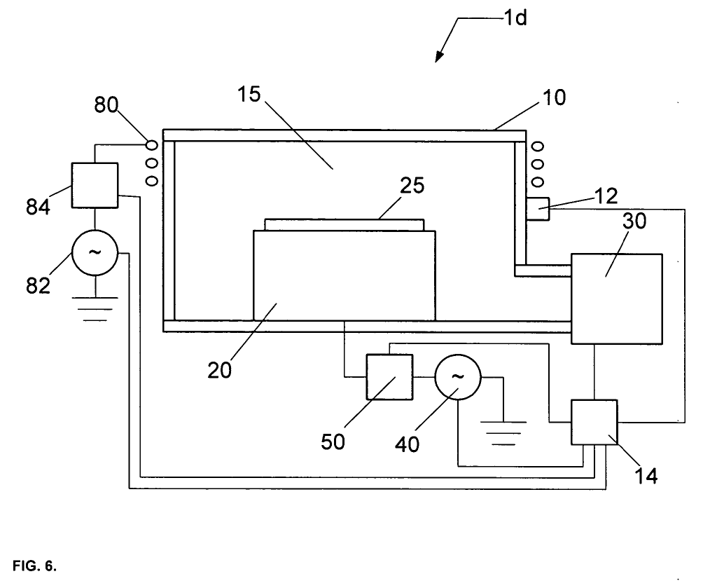

In the embodiment shown in FIG. 6, the plasma processing system 1d can be similar to the embodiments of FIGS. 2 and 3, and can further comprise an inductive coil 80 to which RF power is coupled via RF generator 82 through impedance match network 84. RF power is inductively coupled from inductive coil 80 through a dielectric window (not shown) to plasma processing region 45. A frequency for the application of RF power to the inductive coil 80 can range from about 10 MHz to about 100 MHz. Similarly, a frequency for the application of power to the chuck electrode can range from about 0.1 MHz to about 100 MHz. In addition, a slotted Faraday shield (not shown) can be employed to reduce capacitive coupling between the inductive coil 80 and plasma. Moreover, controller 14 is coupled to RF generator 82 and impedance match network 84 in order to control the application of power to inductive coil 80. In an alternate embodiment, inductive coil 80 can be a “spiral” coil or “pancake” coil in communication with the plasma processing region 15 from above as in a transformer coupled plasma (TCP) reactor. The design and implementation of an inductively coupled plasma (ICP) source, or transformer coupled plasma (TCP) source, is well known to those skilled in the art.

Alternately, the plasma can be formed using electron cyclotron resonance (ECR). In yet another embodiment, the plasma is formed from the launching of a Helicon wave. In yet another embodiment, the plasma is formed from a propagating surface wave. Each plasma source described above is well known to those skilled in the art.

In the following discussion, a method of removing photoresist from a substrate utilizing a plasma processing device is presented. The plasma processing device can comprise various elements, such as described in FIGS. 2 through 6, and combinations thereof.

In one embodiment, the method of removing photoresist comprises an NₓO_{y} based chemistry. For example, a process parameter space can comprise a chamber pressure of about 20 to about 1000 mTorr, an NO process gas flow rate ranging from about 50 to about 1000 sccm, an upper electrode (e.g., element 70 in FIG. 5) RF bias ranging from about 500 to about 2000 W, and a lower electrode (e.g., element 20 in FIG. 5) RF bias ranging from about 10 to about 500 W. Also, the upper electrode bias frequency can range from about 0.1 MHz to about 200 MHz, e.g., about 60 MHz. In addition, the lower electrode bias frequency can range from about 0.1 MHz to about 100 MHz, e.g., about 2 MHz.

In an alternate embodiment, the method of removing photoresist can comprise an NO₂ based chemistry. The process parameter space can comprise a chamber pressure of about 20 to about 1000 mTorr, an NO₂ process gas flow rate ranging from about 50 to about 1000 sccm, an upper electrode (e.g., element 70 in FIG. 5) RF bias ranging from about 500 to about 2000 W, and a lower electrode (e.g., element 20 in FIG. 5) RF bias ranging from about 10 to about 500 W.

In an alternate embodiment, the method of removing photoresist can comprise an N₂O based chemistry. The process parameter space can comprise a chamber pressure of about 20 to about 1000 mTorr, an N₂O process gas flow rate ranging from about 50 to about 1000 sccm, an upper electrode (e.g., element 70 in FIG. 5) RF bias ranging from about 500 to about 2000 W, and a lower electrode (e.g., element 20 in FIG. 5) RF bias ranging from about 10 to about 500 W.

In an alternate embodiment, any mixture thereof can be utilized. In another alternate embodiment, RF power is supplied to the upper electrode and not the lower electrode. In another alternate embodiment, RF power is supplied to the lower electrode and not the upper electrode.

In general, the time to remove the photoresist can be determined using design of experiment (DOE) techniques; however, it can also be determined using endpoint detection. One possible method of endpoint detection is to monitor a portion of the emitted light spectrum from the plasma region that indicates when a change in plasma chemistry occurs due to substantially near completion of the removal of photoresist from the substrate and contact with the underlying material film. For example, portions of the spectrum that indicate such changes comprise wavelengths of 482.5 nm (CO), and can be measured using optical emission spectroscopy (OES). After emission levels corresponding to those frequencies cross a specified threshold (e.g., drop to substantially zero or increase above a particular level), an endpoint can be considered to be complete. Other wavelengths that provide endpoint information can also be used. Furthermore, the etch time can be extended to include a period of over-ash, wherein the over-ash period constitutes a fraction (i.e. 1 to 100%) of the time between initiation of the etch process and the time associated with endpoint detection.

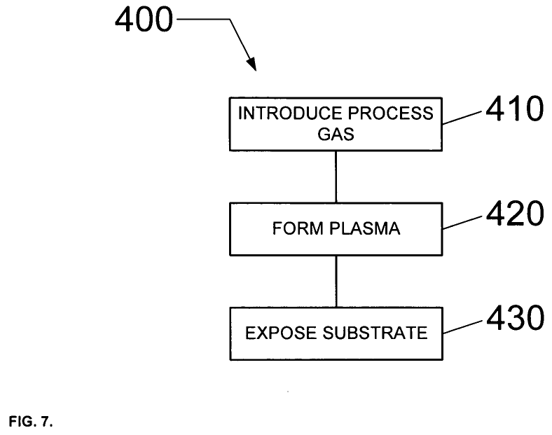

FIG. 7 presents a flow chart of a method for removing photoresist on a substrate in a plasma processing system according to an embodiment of the present invention. Procedure 400 begins in 410 in which a process gas is introduced to the plasma processing system, wherein the process gas comprises NₓO_{y}, wherein x and y are integers greater than or equal to unity. For example, the process gas can comprise NO, NO₂, or N₂O. Alternately, the process gas can further comprise an inert gas, such as a Noble gas (i.e., He, Ne, Ar, Kr, Xe, Rn).

In 420, a plasma is formed in the plasma processing system from the process gas using, for example, any one of the systems described in FIGS. 2 through 6, and combinations thereof.

In 430, the substrate comprising the photoresist layer, or remnants of the photoresist layer, is exposed to the plasma formed in 420. After a first period of time, procedure 400 ends. The first period of time during which the substrate with the photoresist layer is exposed to the plasma can generally be dictated by the time required to ash the photoresist layer. In general, the period of time required to remove the photoresist is pre-determined. Alternately, the period of time can be further augmented by a second period of time, or an over-ash time period. As described above, the over-ash time can comprise a fraction of time, such as 1 to 100%, of the first period of time, and this over-ash period can comprise an extension of ashing beyond the detection of endpoint.

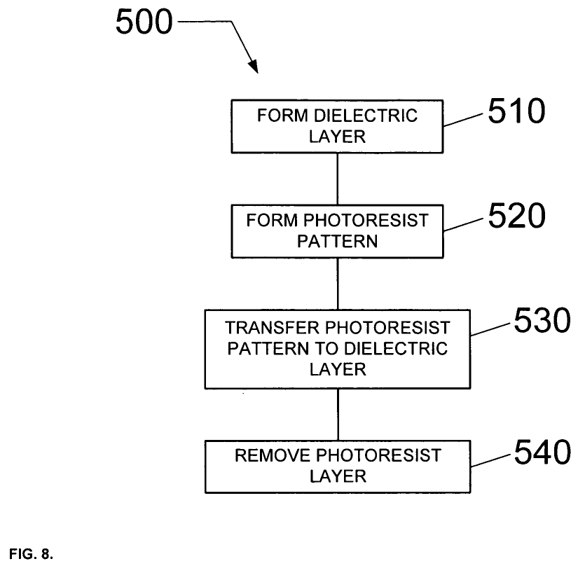

FIG. 8 presents a method of forming a feature in a dielectric layer on a substrate in a plasma processing system according to another embodiment of the present invention. The method is illustrated in a flowchart 500 beginning in 510 with forming the dielectric layer on the substrate. The dielectric layer can comprise an oxide layer, such as silicon dioxide (SiO₂), and it can be formed by a variety of processes including chemical vapor deposition (CVD). Alternately, the dielectric layer has a nominal dielectric constant value less than the dielectric constant of SiO₂, which is approximately 4 (e.g., the dielectric constant for thermal silicon dioxide can range from about 3.8 to about 3.9). More specifically, the dielectric layer may have a dielectric constant of less than about 3.0, or a dielectric constant ranging from about 1.6 to about 2.7.

Alternatively, the dielectric layer can be characterized as a low dielectric constant (or low-k) dielectric film. The dielectric layer may include at least one of an organic, inorganic, and inorganic-organic hybrid material. Additionally, the dielectric layer may be porous or non-porous. For example, the dielectric layer may include an inorganic, silicate-based material, such as oxidized organosilane (or organo siloxane), deposited using CVD techniques. Examples of such films include Black Diamond™ CVD organosilicate glass (OSG) films commercially available from Applied Materials, Inc., or Coral™ CVD films commercially available from Novellus Systems. Additionally, porous dielectric films can include single-phase materials, such as a silicon oxide-based matrix having CH₃ bonds that are broken during a curing process to create small voids (or pores). Additionally, porous dielectric films can include dual-phase materials, such as a silicon oxide-based matrix having pores of organic material (e.g., porogen) that is evaporated during a curing process. Alternatively, the dielectric film may include an inorganic, silicate-based material, such as hydrogen silsesquioxane (HSQ) or methyl silsesquioxane (MSQ), deposited using SOD techniques. Examples of such films include FOx HSQ commercially available from Dow Corning, XLK porous HSQ commercially available from Dow Corning, and JSR LKD-5109 commercially available from JSR Microelectronics. Still alternatively, the dielectric film can include an organic material deposited using SOD techniques. Examples of such films include SiLK-I, SiLK-J, SiLK-H, SiLK-D, and porous SiLK semiconductor dielectric resins commercially available from Dow Chemical, and FLARE™, and Nano-glass commercially available from Honeywell.

In 520, a photoresist pattern is formed on the substrate overlying the dielectric layer. The photoresist film can be formed using conventional techniques, such as a photoresist spin coating system. The pattern can be formed within the photoresist film by using conventional techniques such as a stepping micro-lithography system, and a developing solvent.

In 530, the photoresist pattern is transferred to the dielectric layer in order to form the feature in the dielectric layer. The pattern transfer is accomplished using a dry etching technique, wherein the etch process is performed in a plasma processing system. For instance, when etching oxide dielectric films such as silicon oxide, silicon dioxide, etc., or when etching inorganic low-k dielectric films such as oxidized organosilanes, the etch gas composition generally includes a fluorocarbon-based chemistry such as at least one of C₄F₈, C₅F₈, C₃F₆, C₄F₆, CF₄, etc., and at least one of an inert gas, oxygen, and CO. Additionally, for example, when etching organic low-k dielectric films, the etch gas composition generally includes at least one of a nitrogen-containing gas, and a hydrogen-containing gas. The techniques for selectively etching a dielectric film, such as those described earlier, are well known to those skilled in the art of dielectric etch processes.

In 540, the photoresist pattern, or remaining photoresist, or post-etch residue, etc., are removed. The removal of the photoresist is performed by exposing the substrate to a plasma formed of a process gas comprising NₓO_{y}, wherein x and y are integers greater than or equal to unity. For example, the process gas can comprise NO, NO₂, or N₂O. Alternately, the process gas can further comprise an inert gas, such as a Noble gas (i.e., He, Ne, Ar, Kr, Xe, Rn). Plasma is formed in the plasma processing system from the process gas using, for example, any one of the systems described in FIGS. 2 through 6, and the substrate comprising the photoresist is exposed to the plasma formed. A period of time during which the substrate with the photoresist is exposed to the plasma can generally be dictated by the time required to remove the photoresist. In general, the period of time required to remove the photoresist layer is pre-determined. However, the period of time can be further augmented by a second period of time, or an over-ash time period. As described above, the over-ash time can comprise a fraction of time, such as 1 to 100%, of the period of time, and this over-ash period can comprise an extension of ashing beyond the detection of endpoint.

In one embodiment, the transfer of the photoresist pattern to the dielectric layer, and the removal of the photoresist are performed in the same plasma processing system. In another embodiment, the transfer of the photoresist pattern to the dielectric layer, and the removal of the photoresist are performed in different plasma processing systems.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

1. A method for removing photoresist from a substrate comprising:
disposing said substrate in a plasma processing system, said substrate having a dielectric layer formed thereon with said photoresist overlying said dielectric layer, wherein said photoresist provides a mask for etching a feature into said dielectric layer;
introducing a process gas comprising NₓO_{y}, wherein x and y are integers greater than or equal to unity;
forming a plasma from said process gas in said plasma processing system; and
removing said photoresist from said substrate with said plasma.

2. The method of claim 1, wherein said introducing of said process gas comprises introducing at least one of NO, NO₂, and N₂O.

3. The method of claim 1, wherein said introducing of said process gas further comprises introducing an inert gas.

4. The method of claim 3, wherein said introducing of said inert gas comprises introducing a Noble gas.

5. The method of claim 1, wherein said disposing of said substrate having said dielectric layer comprises disposing said substrate having a low dielectric constant dielectric layer.

6. The method of claim 1, wherein said disposing of said substrate having said dielectric layer comprises disposing said substrate having at least one of a porous dielectric layer, and a non-porous dielectric layer.

7. The method of claim 1, wherein said disposing of said substrate having said dielectric layer comprises disposing said substrate having said dielectric layer including at least one of an organic material, and an inorganic material.

8. The method of claim 7, wherein said disposing of said substrate having said dielectric layer comprises disposing said substrate having said dielectric layer including an inorganic-organic hybrid material.

9. The method of claim 7, wherein said disposing of said substrate having said dielectric layer comprises disposing said substrate having said dielectric layer including an oxidized organo silane.

10. The method of claim 7, wherein said disposing of said substrate having said dielectric layer comprises disposing said substrate having said dielectric layer including at least one of hydrogen silsesquioxane, and methyl silsesquioxane.

11. The method of claim 7, wherein said disposing of said substrate having said dielectric layer comprises disposing said substrate having said dielectric layer including a silicate-based material.

12. The method of claim 9, wherein said disposing of said substrate having said dielectric layer comprises disposing said substrate having said dielectric layer including a collective film including silicon, carbon, and oxygen.

13. The method of claim 12, wherein said disposing of said substrate having said dielectric layer comprises disposing hydrogen in said collective film.

14. A method of forming a feature in a dielectric layer on a substrate comprising:
forming said dielectric layer on said substrate;
forming a photoresist pattern on said dielectric layer;
transferring said photoresist pattern to said dielectric layer by etching; and
removing said photoresist from said dielectric layer using a plasma formed with a process gas comprising NₓO_{y}, wherein x and y are integers greater than or equal to unity.

15. The method of claim 14, wherein said using of said process gas comprises using at least one of NO, NO₂, and N₂O.

16. The method of claim 14, wherein said using of said process gas further comprises using an inert gas.

17. The method as recited in claim 14, wherein said using of said inert gas comprises using a Noble gas.

18. The method as recited in claim 14, wherein said removing of said photoresist is performed for a first period of time.

19. The method as recited in claim 18, wherein said removing of said photoresist for said first period of time is determined by endpoint detection.

20. The method as recited in claim 19, wherein said determining said first period of time by endpoint detection comprises utilizing optical emission spectroscopy.

21. The method as recited in claim 18, wherein said removing of said photoresist for said first period of time is followed by exposing said photoresist to said NₓO_{y} based plasma for a second period of time.

22. The method as recited in claim 21, wherein said exposing for said second period of time comprises exposing said photoresist to said NₓO_{y} based plasma for a fraction of said first period of time.

23. The method as recited in claim 14, wherein said transferring of said photoresist pattern to said dielectric layer by etching is performed in a plasma processing system, and said removing of said photoresist from said dielectric layer is performed in said plasma processing system.

24. The method as recited in claim 14, wherein said transferring of said photoresist pattern to said dielectric layer by etching is performed in a plasma processing system, and said removing of said photoresist from said dielectric layer is performed in another plasma processing system.

25. A plasma processing system for removing photoresist from a substrate comprising:
a plasma processing chamber for facilitating the formation of a plasma from a process gas; and
a controller coupled to said plasma processing chamber and configured to execute a process recipe utilizing said process gas to form a plasma to remove said photoresist from said substrate, wherein said process gas comprises NₓO_{y}, and x and y are integers greater than or equal to unity.

26. The system as recited in claim 25, further comprising a diagnostic system coupled to said plasma processing chamber, and coupled to said controller.

27. The system as recited in claim 26, wherein said diagnostic system is configured to receive a signal that is related to light emitted from said plasma.

28. The system as recited in claim 25, wherein said process gas comprises at least one of NO, NO₂, and N₂O.

29. The system as recited in claim 25, wherein said process gas further comprises an inert gas.

30. The system as recited in claim 25, wherein said inert gas comprises a Noble gas.

31. The system as recited in claim 26, wherein said controller causes said photoresist to be exposed to said plasma for a period of time.

32. The system as recited in claim 31, wherein said period of time is determined by endpoint detection determined by said diagnostic system.

33. The system as recited in claim 26, wherein said diagnostic system comprises an optical emission spectroscopy device.
